(19) United States
(12) Patent Application Publication
(10) Pub. No.: US 2009/0066474 A1
(43) Pub. Date: Mar. 12, 2009

(54) VEHICLE INPUT DEVICE

(75) Inventors: Kazuhiro Kawachi, Aichi-ken (JP); Hirotake Sano, Aichi-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: GToyota Jidosha Kabushiki Kaisha, Aichi-ken (JP)

(21) Appl. No.: 12/299,489

(22) PCT Filed: Jun. 6, 2007
(86) PCT No.: PCT/IB2007/001485

§ 371 Date: Nov. 4, 2008

(30) Foreign Application Priority Data
Jun. 8, 2006 (JP) 2006-159953

(51) Int. Cl. G05B 99/00

(52) U.S. Cl. 340/3.1

(57) ABSTRACT

A vehicle input device includes an operating part arranged within a passenger compartment and a signal processing part that processes signals input through the operating part. The device includes a movable support mechanism that supports the operating part to move between a distant position away from an operator and a nearby position close to the operator, a motor for generating a drive force to displace the operating part, a control part for controlling the motor, and an operation intention detector for detecting an operator's intention to operate the operating part. The control part controls the motor to displace the operating part into the nearby position if the operator's operation intention is detected by the operation intention detector.

### BACKGROUND OF THE INVENTION

1. Field of the Invention

The present invention relates to a vehicle input device having an operating part arranged within a vehicle room and operable by an operator and a signal-processing unit for processing a signal input through the operating part.

2. Description of the Related Art

Conventionally, a vehicle-mounted navigation device characterized by including a moving mechanism for displacing a plurality of touch panel display devices overlappingly positioned to be arranged side by side and also for displacing the display devices arranged side by side back to the original overlappingly stored position is known (see, e.g., Japanese Patent Application Publication No. JP-A-2001-280979).

However, the arrangement position of an operating part operated by a vehicle occupant (operator) is confined within the reach of an operator's hand, which poses a problem in that the degree of freedom of arrangement is reduced. For example, in Japanese Patent Application Publication No. JP-A-2001-280979, the display devices can be moved between a stored position and a deployed position. However, because the display devices are not used when in the stored position, the movable extent of the display devices, when in use, is eventually confined to the reach of an operator's hand. Furthermore, when the operating part is formed of a remote operation controller, it is often difficult to integrally arrange a plurality of the switches in an appropriate position in their entirety.

### SUMMARY OF THE INVENTION

The present invention provides a vehicle input device that arranges an operating part in a desired position when the operating part is not used by detecting an operator's intention to operate the operating part.

A first aspect of the invention is directed to a vehicle input device that includes an operating part arranged within a passenger compartment; signal processing means for processing a signal input through the operating part; a movable support mechanism for supporting the operating part to move between a distant position far away from an operator and a nearby position close to the operator; drive means for generating a drive force to displace the operating part; control means for controlling the drive means; and operation intention detecting means for detecting an operator's intention to operate the operating part, wherein the control means controls the drive means to displace the operating part into the nearby position if the operator's operation intention is detected by the operation intention detecting means.

A second aspect of the invention is directed to the vehicle input device of the first aspect, wherein the control means controls the drive means to displace the operating part into the nearby position if the operator's operation intention is continuously detected for at least a predetermined time period by the operation intention detecting means. This makes it possible to avoid occurrence of erroneous determination by which instantaneous detection of the operator's operation intention is judged to be the detection of the operator's operation intention.

A third aspect of the invention is directed to the vehicle input device of the first or second aspect, wherein the control means controls the drive means to displace the operating part into the distant position if the operator's operation intention is not detected by the operation intention detecting means while the operating part is in the nearby position. This makes it possible to prevent an adverse influence, which would occur if the operating part is unnecessarily kept in the nearby position.

A fourth aspect of the invention is directed to the vehicle input device of any one of the first to third aspects, wherein the operating part includes an operating part of a touch panel display provided on a vehicle instrument panel. This makes it possible to properly maintain operability of the touch panel display, while arranging the touch panel display in the distant position.

A fifth aspect of the invention is directed to the vehicle input device of the fourth aspect, wherein the operation intention detecting means includes a sensor provided on a front surface of the instrument panel for detecting an object approaching or contacting the touch panel display, and the control means controls the drive means to displace the operating part into the nearby position if the object approaching or contacting the touch panel display is detected by the sensor. This makes it possible to detect, with increased accuracy, the operator's intention to operate the touch panel display.

A sixth aspect of the invention is directed to the vehicle input device of any one of the first to third aspects, wherein the operating part includes a main operating member and an auxiliary operating member arranged farther from the operator than the main operating member, wherein the movable support mechanism supports the auxiliary operating member of the operating part to move between the distant position and the nearby position, wherein the operation intention detecting means detects an operator's intention to operate the auxiliary operating member of the operating part, and wherein the control means controls the drive means to displace the auxiliary operating member of the operating part into the nearby position if the operator's operation intention is detected by the operation intention detecting means. This ensures that operability of the auxiliary operating member is increased while keeping operability of the main operating member high. Furthermore, it is possible to enhance operability of the auxiliary operating member and also to improve external appearance of the overall operating part including the auxiliary operating member, if the nearby position is realized by allowing the auxiliary operating member to protrude toward the operator and if the distant position is made come true by retracting the auxiliary operating member.

A seventh aspect of the invention is directed to the vehicle input device of the sixth aspect, wherein the operation intention detecting means includes a photoelectric sensor, arranged at an inside of the main operating member between the main operating member and the auxiliary operating member, for detecting an object interrupting a space of the inside of the main operating member, and the control means controls the drive means to displace the auxiliary operating member of the operating part into the nearby position if the object is detected by the photoelectric sensor. This makes it possible to detect, with increased accuracy, the operator's intention to operate the auxiliary operating member.

An eighth aspect of the invention is directed to the vehicle input device of the sixth aspect, wherein the operation intention detecting means includes a contact detection sensor provided in the main operating member for detecting an object making contact with the main operating member, and the control means controls the drive means to displace the auxiliary operating member of the operating part into the nearby position if the object is detected by the contact detection sensor.

A ninth aspect of the invention is directed to the vehicle input device of the sixth aspect, wherein the control means controls the drive means to displace the auxiliary operating member of the operating part into the distant position if an input operation of the auxiliary operating member is not detected for a predetermined time period or more while the auxiliary operating member of the operating part remains in the nearby position. This makes it possible to prevent an adverse influence, which would occur if the operating part is unnecessarily kept in the nearby position.

A tenth aspect of the invention is directed to the vehicle input device of the sixth aspect, wherein the operator intention detecting means determines the operator's operation intention by voice recognition processing of spoken commands of the operator; and the control means controls the drive means to displace the auxiliary operating member of the operating part into the nearby position based on the voice recognition processing.

An eleventh aspect of the invention is related to a vehicle input device that includes an operating part arranged within a vehicle room and having at least one movable operation switch of a plurality of operation switches; a movable support mechanism for supporting the moveable operation switch of the operating part to move between a distant position far away from an operator and a nearby position close to the operator; drive means for generating a drive force to displace the movable operation switch of the operating part; control means for controlling the drive means; and operation intention detecting means for detecting an operator's intention to operate the movable operation switch of the operating part, wherein the control means controls the drive means to displace the movable operation switch of the operating part into the nearby position if the operator's operation intention is detected by the operation intention detecting means.

A twelfth aspect of the invention is directed to the vehicle input device of the eleventh aspect, wherein the control means controls the drive means to displace the movable operation switch into the distant position if the operator's operation intention is not detected by the operation intention detecting means while the movable operating switch is in the nearby position.

A thirteenth aspect of the invention is directed to the vehicle input device of the eleventh or the twelfth aspect, wherein the operation part includes a remote control means.

A fourteenth aspect of the invention is directed to the vehicle input device of any one of the eleventh to the thirteenth aspects, wherein the plurality of operation switches include a joystick knob operated with two left-right and front-rear axes, and the operation intention detecting means includes at least one photoelectric sensor provided between the movable operation switch and the joystick knob, for detecting an object approaching or making contact with the operation intention detecting means.

A fifteenth aspect of the invention is directed to the vehicle input device of any one of the eleventh to the fourteenth aspects, wherein the operation intention detecting means includes a capacitance sensor provided in at least one of the plurality of operation switches, and the control means controls the drive means to displace the movable operation switch into the nearby position based on an output signal of the capacitance sensor when the operator's hand approaches or makes contact with the corresponding operating switch provided with the capacitance sensor.

### BRIEF DESCRIPTION OF THE DRAWINGS

The above and other objects and features of the present invention will become apparent from the following description of preferred embodiment, given in conjunction with the accompanying drawings, in which:

FIG. 1 is a functional block diagram showing a major configuration of a vehicle input device in accordance with a first embodiment of the present invention;

FIG. 2 is a perspective view illustrating one exemplary condition that the vehicle input device of the present invention is mounted on a motor vehicle;

FIG. 3 is a view showing one example of operation menu images;

FIG. 4A is a view schematically illustrating a condition that a touch panel display is placed in a distant position and FIG. 4B is a view schematically illustrating a condition that the touch panel display is placed in a nearby position;

FIG. 5 is a flowchart illustrating a major process flow performed by an input signal processing part and a motor control part of an operation device control ECU;

FIG. 6 is a view showing one example of layout patterns of an infrared sensor;

FIG. 7 is a view illustrating another layout pattern of the touch panel display;

FIG. 8 is a functional block diagram showing a major configuration of a vehicle input device in accordance with a second embodiment of the present invention;

FIG. 9 is a view showing one example of operation menu images;

FIG. 10 is a top view showing one embodiment of an operating part;

FIGS. 11A and 11B are side perspective views illustrating a joystick knob;

FIG. 12 is a top view illustrating a basic operating posture taken by an operator's hand with respect to the operating part;

FIG. 13A is a view schematically illustrating a condition that an operating switch 6 is placed in a distant position and FIG. 13B is a view schematically illustrating a condition that the operating switch 6 is placed in a nearby position; and

FIGS. 14A and 14B are views showing a modified example of the second embodiment.

### DETAILED DESCRIPTION OF THE PREFERRED EMBODIMENTS

Various embodiments for implementing the present invention will be described hereinafter with reference to the accompanying drawings.

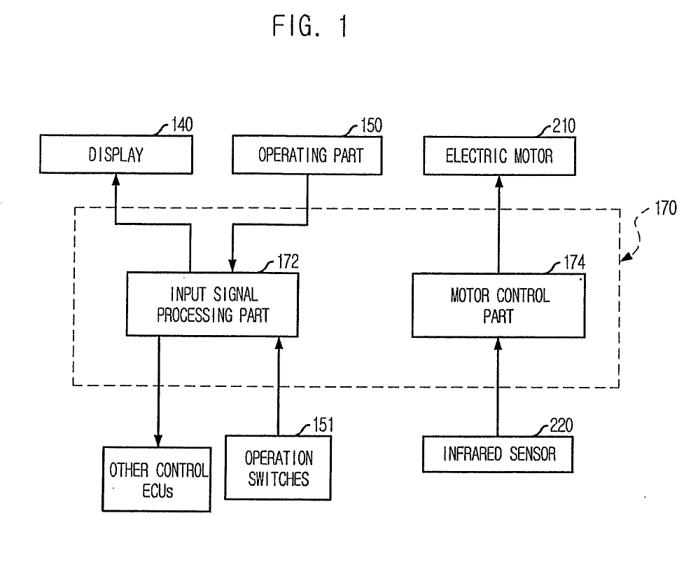

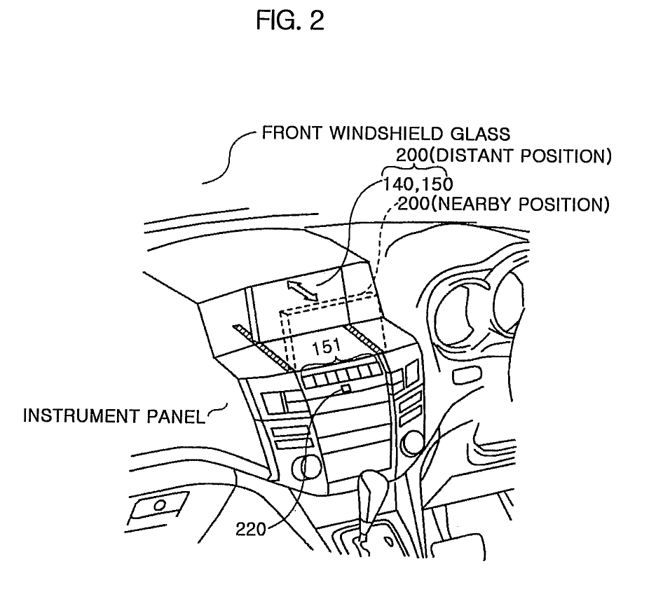

FIG. 1 is a functional block diagram showing a major configuration of a vehicle input device in accordance with a first embodiment of the present invention. FIG. 2 is a perspective view illustrating one exemplary condition that the vehicle input device of the present invention is mounted on a motor vehicle.

As shown in FIG. 1, a vehicle input device of the present embodiment includes an operating part 150, a display 140 and an operation device control ECU 170.

The operating part 150 is provided on the display 140 of a touch panel display 200. That is, both the operating part 150 and the display 140 are implemented by the touch panel display 200 which may be of a typical structure. As illustrated in FIG. 2, the touch panel display 200 is arranged on the instrument panel. The touch panel display 200 is configured such that it can be displaced between a distant position (indicated by a solid line in FIG. 2) far away from an operator and a nearby position (indicated by a broken line in FIG. 2) close to the operator. Detailed description of the above will be given hereinafter.

The operation device control ECU 170 is mainly constructed from a microcomputer. Namely, the operation device control ECU 170 includes a CPU for executing a variety of processing tasks in accordance with a given execution program, a memory (e.g., a ROM, a RAM, an EEPROM or the like) for storing the execution program, an image data, an operation result and the like, a timer, a counter, an input-output interface and so forth. The CPU, the memory and the input-output interface are connected to one another by means of a data bus. Functions of individual parts 172 and 174 of the operation device control ECU 170 described below are realized by a program, which in turn is executed by the CPU.

As shown in FIG. 1, the operation device control ECU 170 includes an input signal processing part 172 and a motor control part 174.

The motor control part 174 of the operation device control ECU 170 controls an electric motor 210, thereby controlling the movement of the touch panel display 200 between the nearby position and the distant position. Detailed descriptions for the above will be given hereinafter.

An infrared sensor 220 is connected to the motor control part 174. The infrared sensor 220 is a reflection type sensor that emits an infrared light from an emitting part thereof and detects in a receiving part thereof the light reflected by an object. The infrared sensor 220 generates a signal corresponding to the detected target object.

As can be seen from FIG. 2, the infrared sensor 220 is installed on a front surface of the instrument panel. The infrared sensor 220 has a detection zone set in such a manner that the infrared sensor 220 detects an object (an operator's hand or an operating mechanism) approaching the touch panel display 200. In the example shown in FIG. 2, the infrared sensor 220 is placed at a frontal center portion of the instrument panel in a position lower than a mounting position of the touch panel display 200 and generally coinciding with a vertical centerline of the touch panel display 200. The optical axis (infrared light emitting direction) of the infrared sensor 220 is oriented slantingly upwardly so as to cover the height extent of the touch panel display 200.

In the example shown in FIG. 2, adjacent to the infrared sensor 220, operation switches 151 serving as an access way for screen operation are arranged in a transverse row. The operation switches 151 are switches of the type operated prior to the operation of an operating part 150 of the touch panel display 200. The operation switches 151 can be, e.g., a switch that brings up a menu option image for destination selection in a car navigation system or a switch that calls up an option image for execution of various selections in an air conditioner system. In the example illustrated in FIG. 2, the infrared sensor 220 is arranged near the center of the row of the operation switches 151.

An operation signal generated by the manipulation of the operation switches 151 and an operation signal (position information) generated by the operation on the operating part 150 of the touch panel display 200 are fed to the input signal processing part 172 of the operation device control ECU 170 via a flexible printed circuit not shown in the drawings. The input signal processing part 172 of the operation device control ECU 170 controls a variety of vehicle-mounted equipments in such a way as to enable the equipments to perform their functions (including the function of converting an operation menu image to another in the display 140) in accordance with the operation signal for the operation switches 151 and the operation signal (position information) for the operating part 150. That is, upon receipt of various operation signals from the operating part 150, the input signal processing part 172 of the operation device control ECU 170 executes a task of converting an image displayed on the display 140 (a task of generating an operation menu image of various operation options set forth below) or other tasks and, at the same time, sends signals corresponding to the various operation signals to additional control ECUs (e.g., a car navigation ECU, an audio ECU, an air conditioner ECU and the like). In response to the signals from the operation device control ECU 170, the additional control ECUs control vehicle-mounted equipments (e.g., a car navigation system, an audio system, an air conditioner and the like) in such a manner as to allow them to perform their functions in accordance with the various operation signals.

The input signal processing part 172 of the operation device control ECU 170 can be, e.g., a part (including a drawing processor) of a navigation device, in which case a map image as well as the operation menu image noted below is displayed on the display 140.

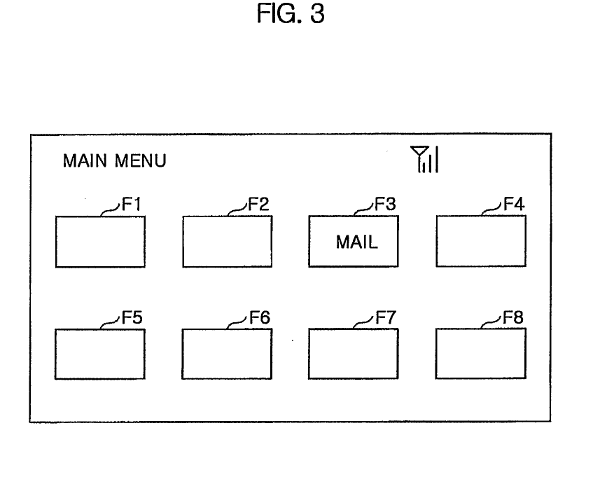

Under the control of the input signal processing part 172 of the operation device control ECU 170, an operation menu image for assisting the operator in operating the operating part 150 may be displayed on the display 140 as illustrated in FIG. 3. The operation menu image shows the arrangement, positions, and functions of operating switches (touch switches) in the operating part 150. The operation menu image informs the operator of the various functions performed by the operation of the operating part 150 and the positions of the individual operating switches, which are to be operated for realization of the various functions.

In the example shown in FIG. 3, the operation menu image includes icons F1-F8 symbolizing eight operating switches in the operating part 150. An operator who looks at the display 140 becomes aware of the fact that the operating switches are arranged in two front and rear rows in the operating part 150 and, by reading a letter written in the individual icons F1-F8, becomes aware of the functions which is executed by operation of the respective operating switches. Taking a specific example, an operator will understand that clicking an operating switch arranged in a position corresponding to the icon F3, with a letter “MAIL”, i.e., an operating switch of the operating part 150 ranked third from the left in the front row, will allow the composition and sending of mail.

The operation menu image may be prepared in plural kinds and can be properly converted to one another depending on the operative condition in the operating part 150. In this instance, the arrangement, positions, and functions of the operating switches in the operating part 150 are changed in compliance with the conversion of the operation menu image. With this configuration, a large number of operating switches for vehicle-mounted equipment may be provided in the operating part 150, thereby assuring efficient concentration of the operating switches. For instance, the operating part 150 may be provided with a variety of operating switches not merely for operation of vehicle information communication equipment used in mailing, calling and neighboring institution guiding but also for diversified operation of an air conditioning device, an audio device and the like (not shown in FIG. 3).

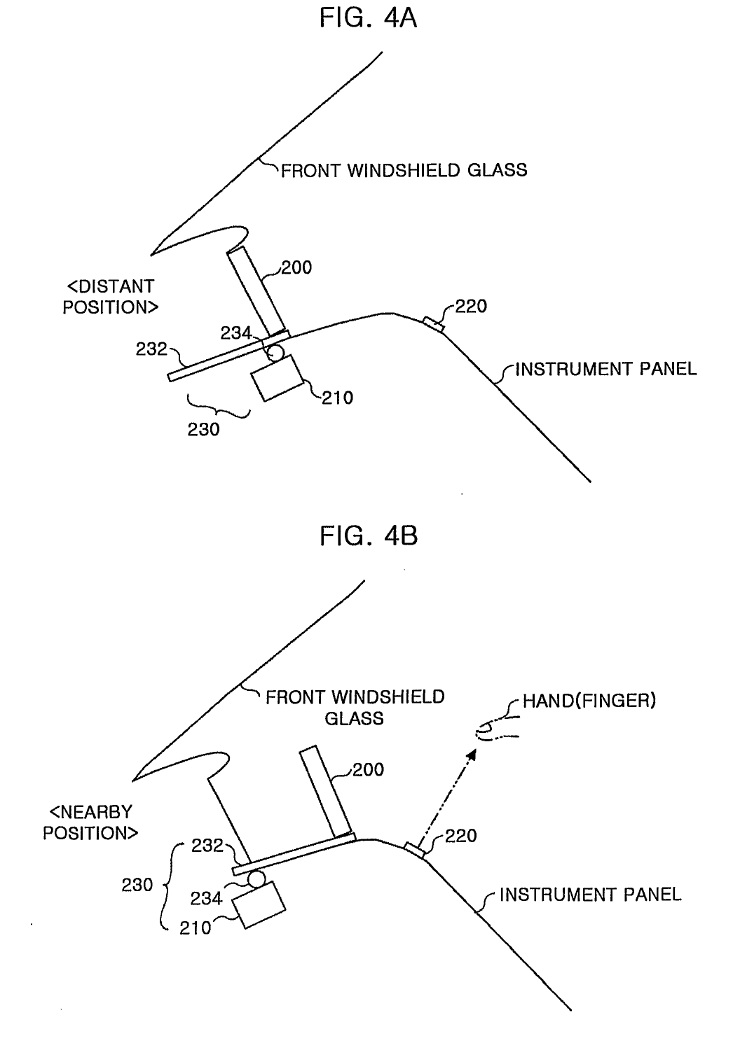

FIG. 4 is a schematic side elevational section view of the vehicle input device shown in FIG. 2. FIG. 4A illustrates a condition that the touch panel display 200 is placed in a distant position and FIG. 4B depicts a condition that the touch panel display 200 is placed in a nearby position.

As illustrated in FIG. 4, the vehicle input device of the present embodiment includes a movable support mechanism 230 for movably supporting the touch panel display 200 and an electric motor 210 for generating a drive force to displace the touch panel display 200.

The movable support mechanism 230 includes a pair of movable rails 232 that fixedly hold the transverse opposite bottom portions of the touch panel display 200 and a pinion 234 engaging with a rack formed on one of the movable rails 232. The pinion 234 is connected to an output shaft of the motor 210 and is rotated by the rotation of the motor 210. The motor 210 is fixedly supported within the instrument panel, whereas the movable rails 232 are supported in such a manner as to move in a vehicle longitudinal direction with respect to the instrument panel. As the motor 210 rotates, the rotational movement thereof is converted to rectilinear movement of the movable rails 232 through the pinion 234 and the rack. If the movable rails 232 are moved closer to an operator, the touch panel display 200 is concomitantly displaced toward a nearby position as illustrated in FIG. 4B. On the other hand, if the movable rails 232 are moved far away from the operator, the touch panel display 200 is concomitantly displaced toward a distant position as illustrated in FIG. 4A. The motor 210 may be provided for each of the movable rails 232 individually or a single motor 210 may be shared by both of the movable rails 232.

As set forth above, in accordance with the present embodiment, it is possible to bring the touch panel display 200 into an optimized position, owing to the fact that the touch panel display 200 is configured in such a fashion as to move between the distant position far away from the operator and the nearby position close to the operator.

The movable support mechanism 230 is not restricted to the rack-and-pinion mechanism employed in this embodiment but can be realized by other gear mechanisms or mechanisms which take advantage of, e.g., X-like arms, wires and so forth. Likewise, the drive unit for generating a drive force to displace the touch panel display 200 is not restricted to the electric motor 210 but can be realized by other actuators such as a solenoid and the like.

In this regard, the distant position of the touch panel display 200 is set to a position in which an operator's line of sight undergoes small change during a driving process. This is because emphasis needs to be placed on the function of the touch panel display 200 as the display 140. Accordingly, the distant position of the touch panel display 200 can be set within an extent in which an operator's hand cannot reach the touch panel display 200 in a typical driving posture. In the ultimate sense, it can be possible to set the distant position of the touch panel display 200 to a position beyond the reach of the operator's hand. Moreover, in the embodiment shown in FIG. 4, the distant position of the touch panel display 200 lies more frontward than and closer to the windshield than a typically available position, as can be seen in FIG. 4A.

On the other hand, the nearby position of the touch panel display 200 is set within an extent in which the operator's hand can reach the touch panel display 200, thus enhancing operability as far as possible. This is because emphasis needs to be placed on the function of the touch panel display 200 as the operating part 150. Moreover, in the embodiment shown in FIG. 4, the nearby position of the touch panel display 200 lies significantly offset toward a rear side of vehicle from a lower end of the windshield, as can be seen in FIG. 4B.

In addition, due to the fact that the displacement stroke of the touch panel display 200 (the movement extent of the movable rails 232) is restricted in terms of design integrity and positional relationship with other vehicle-mounted components, the nearby position and the distant position of the touch panel display 200 are properly selected in due consideration of such restriction and from a view point of the operability and the change of line of operator's sight.

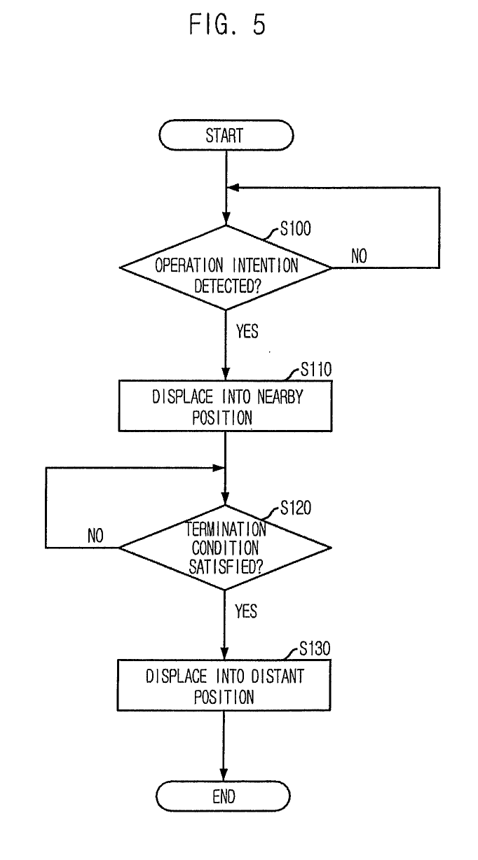

FIG. 5 is a flowchart illustrating a major process flow performed by the motor control part 174 of the operation device control ECU 170.

In step S100, the motor control part 174 determines whether an operator's intention to operate the operating part 150 of the touch panel display 200 is detected. Detection of the operator's operation intention can be determined based on the result of detection of an object in the infrared sensor 220. In this instance, if an operator's hand approaches the operating part 150 of the touch panel display 200 or the operation switches 151 as illustrated by a double-dotted line in FIG. 4B, the infrared sensor 220 detects the operator's hand and regards it as the operator's operation intention. Once the operator's operation intention is detected in this way, the flow proceeds to step S110.

In step S110, the motor control part 174 controls the motor 210 to displace the touch panel display 200 into the nearby position. In a normal condition, the touch panel display 200 is displaced toward and remains in the distant position. Namely, the distant position serves as a default position of the touch panel display 200.

In step S120, determination is made as to whether a termination condition is satisfied, and the touch panel display 200 is kept in the nearby position until the termination condition is satisfied (YES in step S120). The termination condition may denote, e.g., that the touch panel display 200 has not been touched or operated for at least a predetermined time period (e.g., several seconds). Alternatively, the termination condition may denote that a predetermined time period (e.g., several seconds) lapses after the object has not been detected by the infrared sensor 220. In this instance, the termination condition is satisfied and the flow proceeds to step S130, if a predetermined time period lapses after the operator's hand is withdrawn from the touch panel display 200 by terminating the operation of the touch panel display 200, which has moved into the nearby position.

In step S130, the motor control part 174 controls the motor 210 to displace the touch panel display 200 into the distant position. That is, the motor control part 174 controls the motor 210 to return the touch panel display 200 to the original standby position.

As set forth above, in accordance with the present embodiment, it is possible to displace the touch panel display 200 into an optimized position pursuant to the operator's intention to operate. Namely, when the operator's operation intention is detected, the touch panel display 200 may be displaced into the nearby position, thereby enhancing the operability of the operating part 150 of the touch panel display 200. When the operator's operation intention is not detected, the touch panel display 200 may be displaced into the distant position, thereby reducing the change of an operator's sight line when the operator looks at the display 140 of the touch panel display 200 while driving.

Furthermore, in accordance with the present embodiment, because the touch panel display 200 is normally kept in the distant position and is displaced into the nearby position only when the operator's intention to operate is detected, the operator may dispense with a remote operation controller which would otherwise be needed to remotely control the display 140 of the touch panel display 200. This makes it possible to save costs. Generally speaking on the operability of a remote controller and a touch panel, “selection” and “decision” are made at the same time in the touch panel, thus making it possible for the operator to operate the touch panel intuitively. In contrast, in the remote controller, “selection” and “decision” are made through separate operations. Thus, the touch panel is superior in operability to the remote controller on the underlying principle. Accordingly, in accordance with the present embodiment, it is possible to enhance the operability of the touch panel display 200 because a remote operation controller is not needed even when the display 140 is placed in the distant position. However, the present invention does not exclude the provision of a separate remote operation controller. It is a matter of course that the remote operation controller may be additionally provided to assure convenience of operation from, for example, the rear seat or to meet the diversity of operators' preference.

Furthermore, in accordance with the present embodiment, because the touch panel display 200 is displaced from the distant position to the nearby position if the operator operates or attempts to operate the operation switches 151, it is possible for the operator to naturally shift from the operation of the operation switches 151 to the operation of the operating part 150 of the touch panel display 200 displaced into the nearby position. In addition, it takes for granted that touch switches operable without resort to the operation switches 151 can be provided on the operating part 150 of touch panel display 200. In this instance, just like the preceding case, the touch panel display 200 is displaced from the distant position to the nearby position if the operator attempts to operate the touch switches on the operating part 150 of the touch panel display 200. Thus, the operator is able to execute operation of the touch switches without having to overly change his or her posture.

In the present embodiment, the motor control part 174 may displace the touch panel display 200 into the nearby position if the operator's operation intention continues to be detected for at least a predetermined time period. Specifically, the motor control part 174 displaces the touch panel display 200 into the nearby position if the operator's hand is continuously detected by the infrared sensor 220 for at least a predetermined time period. This is to eliminate noises that would otherwise be generated when that the operator's hand is instantaneously detected by the infrared sensor 220 in the course of movement of the operator's hand with no operation intention. This is also based on the fact that, insofar as the operator has explicit operation intention, the operator's hand would be surely detected for a predetermined time period or more. The predetermined time period can be a value in the range of, e.g., about 0.5 to 1 second. By eliminating noises in this way, it is possible to increase the accuracy of detection of the operator's operation intention.

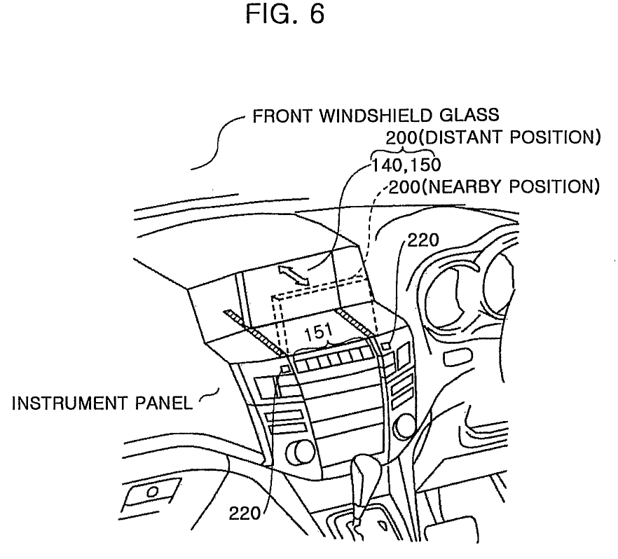

Furthermore, in the present embodiment, two or more infrared sensors 220 may be installed to increase reliability. For instance, as illustrated in FIG. 6, two infrared sensors 220 may be provided in the positions corresponding to the transverse opposite ends of the touch panel display 200 (at the opposite ends of the row of operation switches 151) in a one-to-one correspondence. In this instance, the operator's operation intention may be regarded as having been detected when the operator's hand is sensed by both of the infrared sensors 220. As in the preceding case, the touch panel display 200 may be also allowed to move into the nearby position in case the operator's hand is continuously detected by both of the infrared sensors 220 for at least a predetermined time period. In the example illustrated in FIG. 6, the two infrared sensors 220 may also be arranged in such a fashion that optical axes thereof can intersect with each other substantially at a transverse center of the touch panel display 200.

Additionally, in the present embodiment, other kinds of sensors such as a visible-ray-based photoelectric sensor, a transmission type photoelectric sensor and a regression reflection type photoelectric sensor can be used in place of or in addition to the infrared sensor 220.

Furthermore, in the present embodiment, as a failsafe for coping with the occurrence of trouble or the like in the infrared sensor 220, it can be possible to ensure that, even in case of the infrared sensor 220 failing to detect the operator's operation intention, the motor control part 174 judges the operator's operation intention to have been detected and displaces the touch panel display 200 into the nearby position, insofar as touch or operation for the operating part 150 of the touch panel display 200 or the operation switches 151 is actually detected.

Moreover, in the present embodiment, it can be possible to determine presence or absence of the operator's operation intention based on other inputs from the operator in place of or in addition to the detection made by the infrared sensor 220. For example, the operator's operation intention can be judged by voice recognition processing of spoken commands of the operator. In this instance, the motor control part 174 can be configured to displace the touch panel display 200 into the nearby position in response to an spoken command of the operator in the meaning of, e.g., “move to the nearby position” or “start operation”. Similarly, if an indoor camera is provided, it can be possible to determine presence or absence of the operator's operation intention based on an image recognition result for an image taken by the camera. In this instance, the motor control part 174 may be configured to displace the touch panel display 200 into the nearby position when the operator's hand is image-recognized. Alternatively, the motor control part 174 may displace the touch panel display 200 into the nearby position when a specific gesture of the operator is image-recognized.

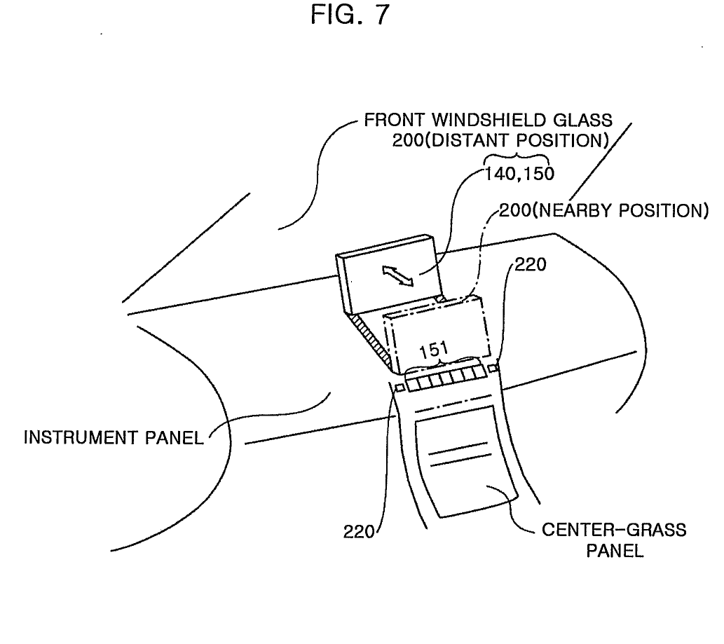

Furthermore, in the present embodiment, the touch panel display 200 may be mounted on a top portion of the instrument panel as illustrated in FIG. 7. That is, unlike the example shown in FIG. 2 in which the touch panel display 200 is configured to mounted within a cavity formed below a hood on the top portion of the instrument panel, the touch panel display 200 can be mounted on the top portion of the instrument panel in an exposed condition as depicted in FIG. 7.

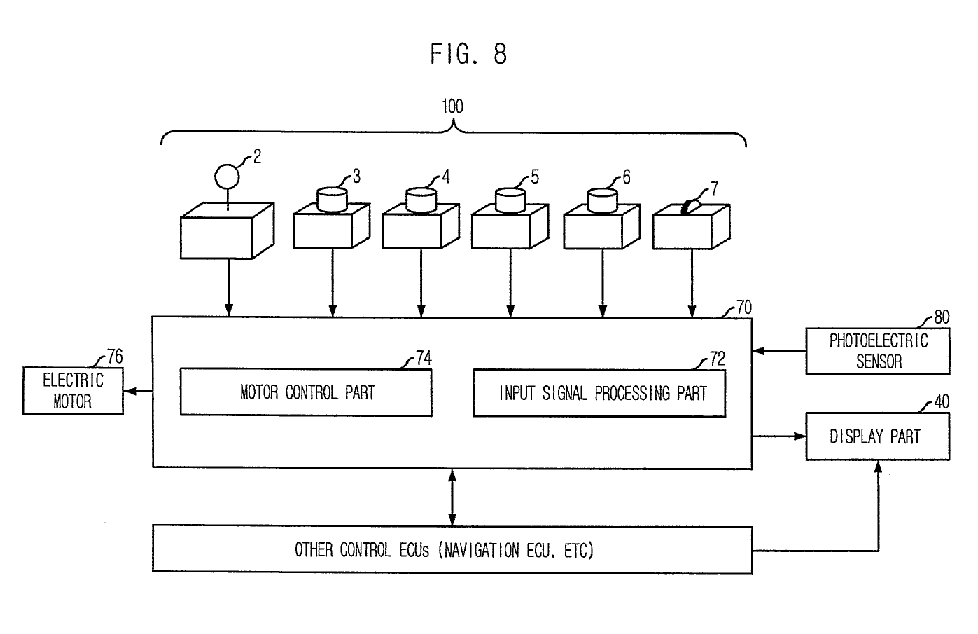

FIG. 8 is a functional block diagram showing a major configuration of a vehicle input device in accordance with a second embodiment of the present invention. Referring to FIG. 8, the vehicle input device of the present embodiment includes an operating part 100 serving as a remote operation controller and an operation device control ECU 70.

The operation device control ECU 70 is mainly implemented by using a microcomputer. Namely, the operation device control ECU 70 includes a CPU for executing a variety of processing tasks in accordance with a given operation program, a memory (e.g., a ROM, a RAM, an EEPROM or the like) for storing the operation program, an image data, an operation result and the like, a timer, a counter, an input-output interface and so forth. The CPU, the memory and the input-output interface are connected to one another by means of a data bus. Functions of individual parts 72 and 74 of the operation device control ECU 70 described below are implemented by a program, which in turn is executed by the CPU.

As shown in FIG. 8, the operation device control ECU 70 includes an input signal processing part 72 and a motor control part 74.

The input signal processing part 72 of the operating device control ECU 70 performs wire communication or wireless communication with the operating part 100. Upon receiving various operation signals from the operating part 100, the input signal processing part 72 of the operation device control ECU 70 converts an image displayed on a display part 40 (generating an operation menu image of various operation options set forth below) or other tasks and, at the same time, sends signals corresponding to the various operation signals to additional control ECUs (e.g., a car navigation ECU, an audio ECU, an air conditioner ECU and the like). In response to the signals from the operation device control ECU 70, the additional control ECUs control vehicle-mounted equipment (e.g., a car navigation system, an audio system, an air conditioner and the like) in such a manner as to allow them to perform their functions in accordance with the various operation signals.

The motor control part 74 of the operation device control ECU 70 serves to control an electric motor 76, thereby controlling movement of an operating switch 6 between a nearby position and a distant position. Detailed description in this regard will be given later.

A photoelectric sensor 80 is connected to the motor control part 74. The photoelectric sensor 80 is a reflection type sensor that emits an infrared light or a visible ray from an emitting part thereof and detects in a receiving part thereof the light or ray reflected by an object. The photoelectric sensor 80 generates a signal corresponding to a target detection object.

The display part 40 may be constructed from a liquid crystal display or the like and is arranged in an easy-to-see position from the standpoint of an operator, i.e., in a position in which the operator can look at the display part 40 without overly changing his or her field of view when driving. For example, the display part 40 may be arranged at a center portion of a top surface of the instrument panel, at an upper center portion of a front surface of the instrument panel or within a meter panel section. Furthermore, seeing that the display part 40 not to be a touch panel display in the second embodiment, the display part 40 may be arranged with no consideration of operability insofar as it is not a touch panel display.

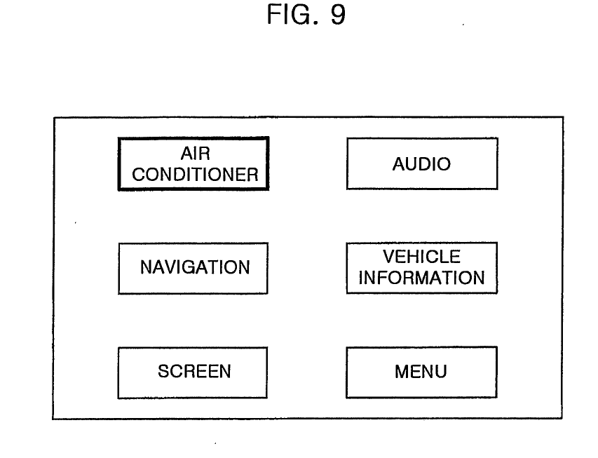

Under the control of the operation device control ECU 70, an operation menu image for assisting an operator in operating the operating part 100 is displayed on the display part 40 as illustrated in FIG. 9. The operation menu image shows icons of option buttons that represent the functions executable by making operation in the operating part 100. Based on operation signals from the operating part 100, the operating device control ECU 70 highlights a currently selected option button (an “air conditioner” button in this example). Thus, the operator (a driver seat occupant or a front passenger seat occupant) can easily determine the option button that is currently selected. The operating part 100 and the display part 40 are separately arranged in physically isolated positions within a vehicle room. The operator operates the operating part 100 while seeing the display part 40, which is often referred to as “blind operation”.

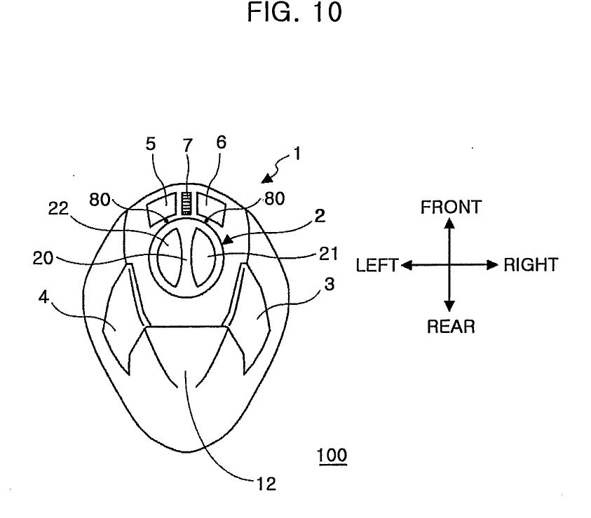

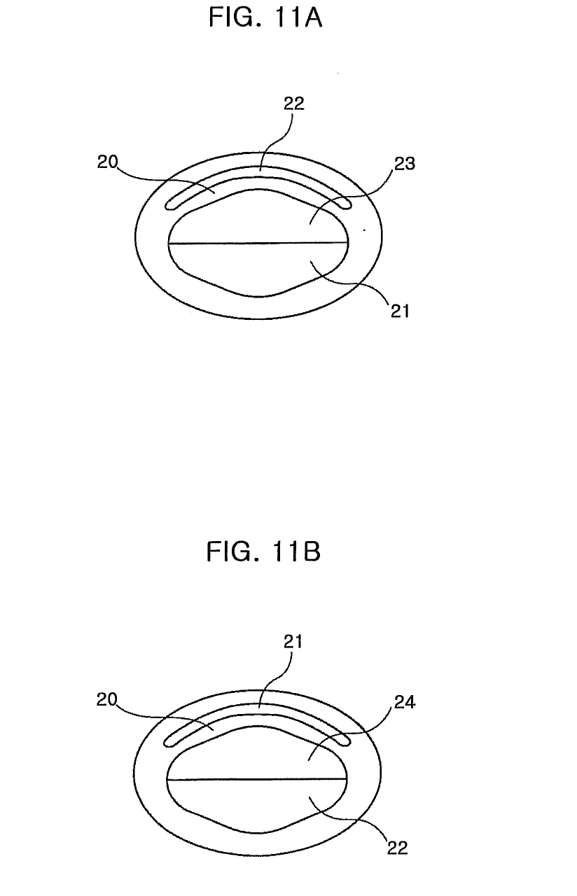

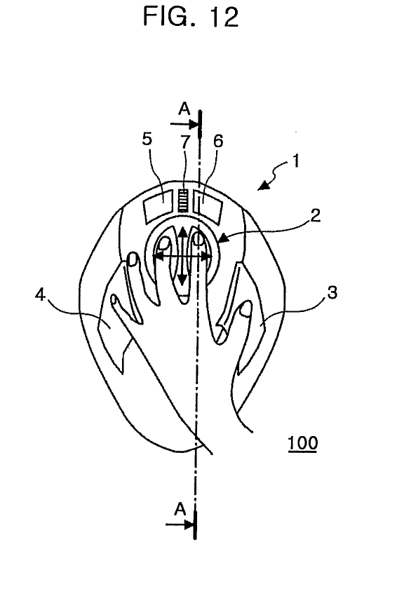

FIG. 10 is a top view showing one embodiment of the operating part 100. FIG. 11 is a side elevational perspective view illustrating a joystick knob 2. FIG. 12 is a top view illustrating a basic operating posture when the operator's left hand is placed on the operating part 100.

In the example illustrated in FIG. 10, the operating part 100 includes a housing 1, a joystick knob (operating knob) 2 as a main operating member, operating switches 3 and 4, operating switches 5 and 6 as an auxiliary operating member, and a dial switch 7. The operating part 100 is substantially bilaterally symmetrical. The housing 1, the joystick knob 2 and the operating switches 3-6 are operated to effectuate various functions of, e.g., a car navigation system, an audio system, an air conditioner and so forth. The operating part 100 is installed at an easy-to-operate location from the viewpoint of a vehicle occupant, such as a vehicle center portion (e.g., a center console) not shown in the drawings.

As illustrated in FIG. 10, the housing 1 constitutes an external surface (design surface) of the operating part 100 and includes a palm rest portion 12 for stably supporting an operator's palm during operation. As will be set forth below, the palm rest portion 12 lies in a position where individual fingers are allowed to share switch operation roles, and has an exterior surface formed into a convex sphere shape.

The joystick knob 2 is positioned more frontward than the palm rest portion 12 at a center portion of the housing 1. As shown in FIG. 12, the joystick knob 2 is operated by an index finger and a middle finger under the condition that the palm is laid on the palm rest portion 12. The joystick knob 2 is a retractable operating member that can be operated two-dimensionally (with two left-right and front-rear axes) as indicated by arrows in FIG. 12. The joystick knob 2 is rotatably supported within the housing 1 by a spherical bearing for rotation with respect to the housing 1, for example. A rotary encoder (not shown) for detecting a rotation amount of the joystick knob 2 is provided in the place where rotation occurs. The rotation amount about a left-right axis and the rotation amount about a front-rear axis of the joystick knob 2 are detected by the rotary encoder and fed to the input signal processing part 72 of the operating device control ECU 70.

The joystick knob 2 may be operated in order to, e.g., change selection of option buttons in the display portion 40. Referring to the display image of the display portion 40 shown in FIG. 9, if the operator tilts the joystick knob 2 to the right, an operation signal corresponding thereto is input to the input signal processing part 72 of the operating device control ECU 70. In response to the operation signal thus input, the input signal processing part 72 shifts current button selection from the “AIR CONDITIONER” button to an “AUDIO” button. Likewise, if the operator tilts the joystick knob 2 toward the nearby position (in the backward direction in the drawings), an operation signal corresponding thereto is input to the input signal processing part 72 of the operating device control ECU 70. In response to the operation signal thus input, the input signal processing part 72 shifts the current button selection from the “AIR CONDITIONER” button to a “NAVIGATION” button. Moreover, if the operator tilts the joystick knob 2 obliquely to the right and backward direction, an operation signal corresponding thereto is input to the input signal processing part 72 of the operating device control ECU 70. In response to the operation signal thus input, the input signal processing part 72 shifts current button selection from the “AIR CONDITIONER” button to a “VEHICLE INFORMATION” button.

As shown in FIGS. 10 and 11, the joystick knob 2 includes a protrusion portion 20 that may be interposed between the index finger and the middle finger of a left hand and depression portions 21 and 22 for accommodating the index finger and the middle finger. Opposite flank surfaces 23 and 24 of the protrusion portion 20 and the depression portions 21 and 22 extend in the longitudinal direction of the fingers so that they facilitate contact with the side and bottom portions of the two fingers (with first segment portions of the fingers) over a predetermined length.

The operating switches 5 and 6 may be, e.g., electric contact switches, and are arranged in front of the joystick knob 2 (see an arrow indication shown in FIG. 10). Detailed description will be given later in respect of the operating switches 5 and 6.

As can be seen in FIG. 10, the photoelectric sensor 80 is provided between the operating switch 6 and the joystick knob 2. The photoelectric sensor 80 has a detection region that is set so that the photoelectric sensor 80 detects an object (an operator's hand or an operating mechanism) moving toward the operating switch 6. In the illustrated embodiment, the photoelectric sensor 80 has an optical axis (a light emitting direction) oriented substantially upwardly.

The dial switch 7 is a switch arranged more frontward than the projection portion 20 of the joystick knob 2 and used for the purpose of setting levels of an item with a plurality of selectable levels, e.g., to enlarge or reduce the scale of a map displayed on the display part 40 or to control the volume of the audio system. The map may be enlarged by turning the dial switch 7 in the forwards (toward the top in the figure) and may be reduced by turning the dial switch 7 in the rearwards (toward the bottom in the figure). The operator may operate the dial switch 7 by slightly stretching in the front direction (toward the top in the figure) the index finger placed in the depression portion 21 or the middle finger lying in the depression portion 22.

The operating switch 3 can be, e.g., an electric contact switch, and is arranged on the right of the joystick knob 2. Similarly, the operating switch 4 can be, e.g., an electric contact switch, and is arranged on the left of the joystick knob 2. The operating switches 3 and 4 may be arranged substantially in a bilaterally symmetrical relationship in the operating part 100. As illustrated in FIG. 12, the operating switches 3 and 4 may be arranged in such a position and extent as to ensure that the thumb and the little finger of the operator lie in place naturally, when the palm is placed on the palm rest portion 12 with the joystick knob 2 interposed between the index finger and the middle finger.

Functions that are frequently used are assigned to the operating switches 3 and 4, in view of the fact that, as with the joystick knob 2, the operating switches 3 and 4 may be operated by the thumb and the little finger when the palm is placed on the palm rest portion 12 but without changing the position of the operator's hand. Unlike the index finger and the middle finger, the thumb and the little finger are not used in typical switch operations. In the present embodiment, however, it is possible to improve both versatility and operability of switches by employing a switch arrangement that allows the thumb and the little finger to be used in the switch operations.

A function of a “decision-malding” switch may be allotted to the operating switch 3, while allotting a function of a “return” switch to the operating switch 4. In this case, as illustrated in FIG. 12, the operator seated in the driver's seat can effectuate the function of a “decision-making” switch by operating the right operating switch 3 with the left-hand thumb when the palm of the left hand is placed on the palm rest portion 12. The function of a “return” switch can be effectuated by operating the left operating switch 4 with the little finger of the left hand. The “decision-making” switch is a switch for fixing or finalizing the selection of a “currently selected option button” which can be changed by inputting the directional operation of the joystick knob 2. The “return” switch is a switch for canceling the selection of an option button inadvertently fixed by the “decision-making” switch or the attendant conversion of an image and for allowing the operator to make selection once again.

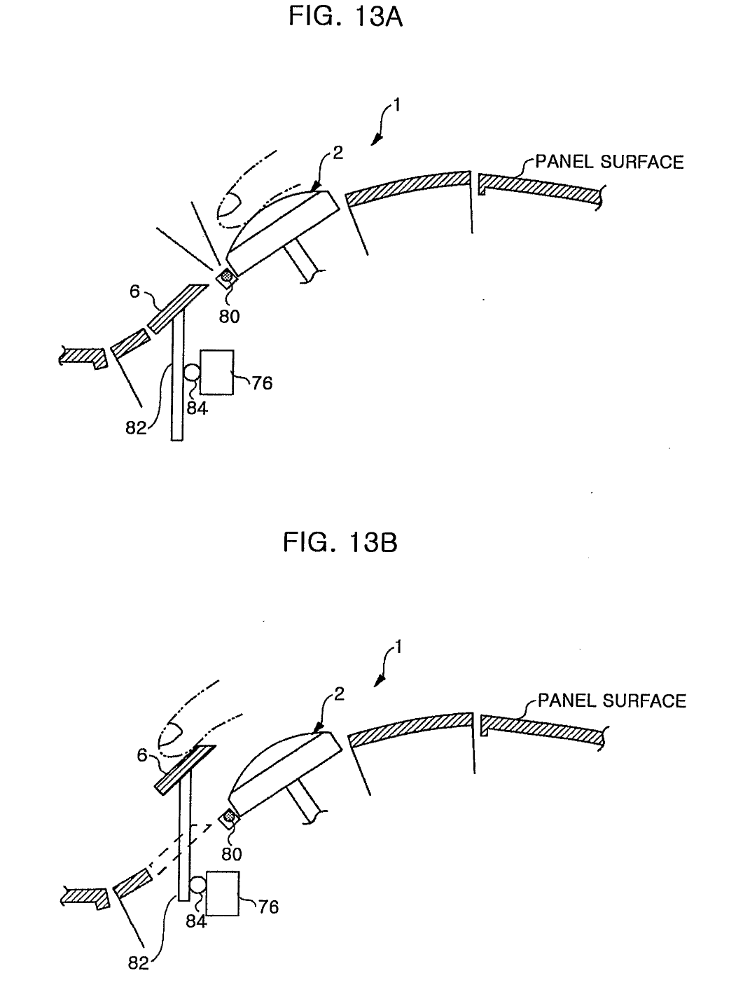

FIGS. 13A and 13B are sectional views taken along line A-A in FIG. 12. FIG. 13A illustrates a condition that the operating switch 6 is placed in the distant position and FIG. 13B illustrates a condition that the operating switch 6 is placed in the nearby position. Although the following description is directed to a configuration of the operating switch 6, the same description applies to the operating switch 5 unless otherwise specifically stated.

As illustrated in FIGS. 13A and 13B, the vehicle input device of the present embodiment includes a movable support mechanism for movably supporting the operating switch 6 and an electric motor 76 for generating a drive force to displace the operating switch 6.

The movable support mechanism includes a movable support arm 82 fixedly secured to the underside of the operating switch 6 and a pinion 84 that engages a rack formed on the movable support arm 82. The pinion 84 is connected to the output shaft of the motor 76 and is rotated upon rotation of the motor 76. The motor 76 is fixedly supported on the housing 1, whereas the movable support arm 82 is supported on the housing 1 in a manner that permits movement in the up-and-down direction on the skew along a vehicle longitudinal direction. As the motor 76 rotates, the rotational movement thereof is converted to rectilinear movement of the movable support arm 82 through the pinion 84 and the rack of the movable support arm 82. If the movable support arm 82 is moved closer to the operator (moved obliquely upwardly), the operating switch 6 is concomitantly displaced toward a nearby position and thus comes into a protruding condition as illustrated in FIG. 13B. On the other hand, if the movable support arm 82 is moved far away from the operator (moved obliquely downwardly), the operating switch 6 is concomitantly displaced toward a distant position and comes into a retracted condition as illustrated in FIG. 13A.

The motor 76 may be separately provided for each of the operating switches 5 and 6 or the operating switches 5 and 6 may share a single motor 76. In the latter case, a rack-and pinion mechanism may be used to operate switch 5 by allowing a movable support arm of the same structure as that of the movable support arm 82 to engage with the output shaft of the motor 76.

The motor control part 74 of the operating device control ECU 70 controls the motor 76 based on an output result of the photoelectric sensor 80, thereby controlling the movement of the operating switch 6 between the nearby position and the distant position. This control method may be substantially the same as the control method shown in FIG. 5 and described above with regard to the first embodiment. Specifically, based on the periodic outputs from the photoelectric sensor 80, the motor control part 74 determines whether the operator intends to operate the operating switch 6. In this instance, if an operator's hand comes closer to the operating switch 6, as illustrated by a double-dotted line in FIG. 13B, the photoelectric sensor 80 detects the operator's hand and regards it as the operator's operation intention. Once the operator's operation intention is detected in this way, the motor control part 74 controls the motor 76 to displace the operating switch 6 into the nearby position. Normally, the operating switch 6 remains in the distant position (in the retracted condition). That is, the distant position serves as a default position of the operating switch 6. Once the operating switch 6 is displaced into the nearby position, the motor control part 74 determines whether a predetermined termination condition is met, by monitoring the periodic outputs from the photoelectric sensor 80 or the situation of generation of an operating signal. The motor control part 74 maintains the operating switch 6 in the nearby position until the termination condition is satisfied. The termination condition may denote, e.g., that the operating switch 6 is not touched or operated for at least a predetermined time period (e.g., several seconds). In this case, the termination condition is satisfied if the operating switch 6 is not operated for at least the predetermined time period after the operating switch 6 has moved into the nearby position. If the termination condition is satisfied, the motor control part 74 controls the motor 76 to displace the operating switch 6 into the distant position. That is, the motor control part 74 controls the motor 76 in such a manner as to return the operating switch 6 to the original standby position.

As set forth above, in accordance with the present embodiment, it is possible to bring the operating switch 6 into an optimized position pursuant to the operator's operation intention. In other words, because the operating switch 6 is moved to the nearby position in case of detection of the operator's operation intention, the operator is able to operate the operating switch 6 without having to excessively change the position of his or her hand currently operating the joystick knob 2. This enhances the operability of the operating switch 6, placed far away from operator. In case of non-detection of the operation intention, the operating switch 6 is displaced into the distant position, which helps to keep operability of the joystick knob 2 intact. This also improves external appearance of the operating part 100.

Because the operability of operating switches 5 and 6 may be enhanced, even if placed in a distant position, as described above, it can be possible to assign frequently-used functions, such as a “start” function, a “map” function or the like, to the operating switches 5 and 6. In other words, the function of a switch (operation switch) for gaining access to a lower tier of a hierarchical menu may be assigned to the operating switches 5 and 6.

The present embodiment is particularly suitable for a remote operation controller in which a plurality of switches 2, 3, 4, 5, 6 and 7 are collectively arranged, as in the operating part 100. The reason is that it is difficult for the remote operation controller to arrange its entire switches in appropriate positions, thus making it inevitable to arrange a certain number of switches (the operating switches 5 and 6 in the present embodiment) in hard-to-operate positions.

In the present embodiment, it is preferred that the motor control part 74 displaces the operating switch 6 into the nearby position if the operator's operation intention continues to be detected for at least a predetermined time period. Specifically, the motor control part 74 displaces the operating switch 6 into the nearby position when the operator's hand is continuously detected by the photoelectric sensor 80 for at least a predetermined time period. This eliminates noises that would otherwise be generated in such a case that the operator's hand is instantaneously detected by the photoelectric sensor 80 in the course of movement of the operator's hand with no operation intention. This is also based on the fact that, if the operator intends to operate the operating part, the operator's hand would be detected for at least a predetermined time period. The predetermined time period can be a value in the range of, e.g., about 0.5 to 1 second. By eliminating noises in this way, it is possible to increase the accuracy of detection of the operator's operation intention.

Furthermore, in the present embodiment, two or more photoelectric sensors 80 can be installed in an effort to increase reliability. For the cost saving purpose, a single photoelectric sensor 80 can be used in common for the operating switches 5 and 6. Additionally, in the present embodiment, other kinds of sensors, such as a transmission type photoelectric sensor, a regression reflection type photoelectric sensor and the like, may be used in place of the photoelectric sensor 80.

Moreover, in the present embodiment, it is possible to determine presence or absence of the operator's operation intention based on other inputs from the operator in place of or in addition to the detection made by the photoelectric sensor 80. For example, the operator's operation intention assessed by voice recognition processing of utterances by the operator or based on an image recognition result of an operator's gesture, as set forth earlier.

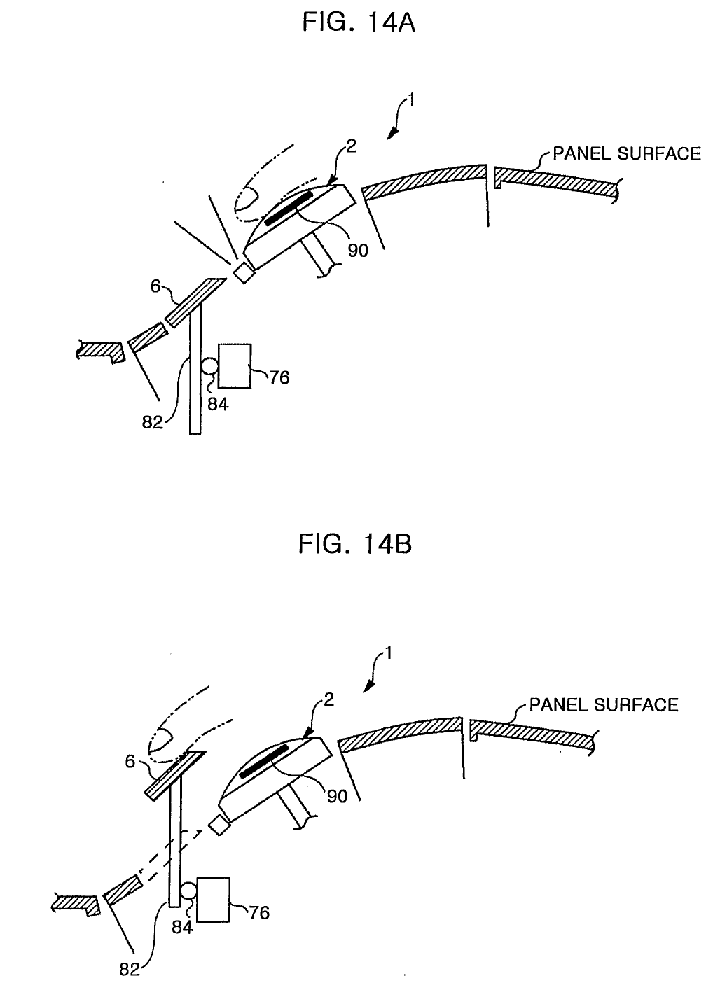

FIGS. 14A and 14B are views showing a modified example of the second embodiment and correspond to the sectional views taken along line A-A in FIG. 12. FIG. 14A illustrates the placement of the operating switch 6 in the distant position and FIG. 14B shows the placement of the operating switch 6 in the nearby position. In this modified example, as illustrated in FIGS. 14A and 14B, a capacitance sensor 90 may be provided in the joystick knob 2 in place of or in addition to the photoelectric sensor 80. In this case, based on an output signal of the capacitance sensor 90, the motor control part 74 may determine that the operator intends to operate the operating switches 5 and 6, and then displace the operating switches 5 and 6 into the nearby position, in case the operator's hand makes contact with or gets closer to the joystick knob 2 as illustrated in FIG. 14A.

While the invention has been described in detail with respect to the preferred embodiments, it will be understood by those skilled in the art that the present invention is not limited to the foregoing embodiments but various changes and modifications can be made without departing from the scope of the invention as defined in the claims.

For example, unlike the forgoing embodiments in which the touch panel display 200 or the like is displaced in two stages between the distant position and the nearby position, the touch panel display 200 or the like can be displaced in three or more stages. Furthermore, the distant position and the nearby position may be adjusted by the operator.

In accordance with the present invention described above, there is provided a vehicle input device that makes it possible to arrange an operating part in a desired position when the operating part is not used by detecting an operator's intention to operate the operating part.

While the present invention has been described with respect to certain preferred embodiments, it will be apparent to those skilled in the art that various changes and modifications can be made without departing from the spirit and scope of the invention as defined in the following claims.

1-17. (canceled)

18: A vehicle input device comprising:
an operating part, arranged within a vehicle passenger compartment;
a signal processing device for processing a signal input through the operating part;
a movable support mechanism that supports the operating part to move between a distant position farther away from an operator and a nearby position closer to the operator;
a driving device for generating a drive force to displace the operating part;
a controller for controlling the driving device; and
an operation intention detector for detecting an operator's intention to operate the operating part,
wherein the controller controls the driving device to displace the operating part into the nearby position if the operator's operation intention is detected by the operation intention detector,
wherein the operating part comprises a main operating member and an auxiliary operating member, arranged farther from the operator than the main operating member, wherein the movable support mechanism supports the auxiliary operating member of the operating part to move between the distant position and the nearby position, wherein the operation intention detector detects an operator's invention to operate the auxiliary operating member of the operating part, and wherein the controller controls the driving device to display the auxiliary operating member of the operating part into the nearby position if the operator's operation intention is detected by the operating intention detector,
wherein the operation intention detector comprises a photoelectric sensor arranged at an inside of the main operating member between the main operating member and the auxiliary operating member for detecting an object interrupting a space at the inside of the main operating member, and
the controller controls the driving device to displace the auxiliary operating member of the operating part into the nearby position if the object is detected by the photoelectric sensor.

19: The vehicle input device according to claim 18, wherein the controller controls the driving device to displace the operating part into the nearby position if the operator's operation intention is detected for at least a predetermined time period by the operation intention detector.

20: The vehicle input device according to claim 18, wherein the controller controls the driving device to displace the operating part into the distant position if the operator's operation intention is not detected by the operation intention detector while the operating part is in the nearby position.

21: The vehicle input device according to claim 19, wherein the controller controls the driving device to displace the operating part into the distant position if the operator's operation intention is not detected by the operation intention detector while the operating part is in the nearby position.

22: The vehicle input device according to claim 18, wherein the operating part comprises an operating part of a touch panel display provided on a vehicle instrument panel.

23: The vehicle input device according to claim 22, wherein the operation intention detector comprises a sensor, provided on a front surface of the instrument panel, that detects an object approaching or making contact with the touch panel display, and the controller controls the driving device to displace the operating part into the nearby position if the object approaching or making contact with the touch panel display is detected by the sensor.

24: The vehicle input device according to claim 18, wherein the operation intention detector comprises a contact detection sensor provided in the main operating member for detecting an object making contact with the main operating member, and wherein the controller controls the driving device to displace the auxiliary operating member of the operating part into the nearby position if the object is detected by the contact detection sensor.

25: The vehicle input device according to claim 18, wherein the controller controls the driving device to displace the auxiliary operating member of the operating part into the distant position if an input operation of the auxiliary operating member is not detected for at least a predetermined time period while the auxiliary operating member of the operating part remains in the nearby position.

26: The vehicle input device according to claim 18, wherein the operator intention detector is adapted to determine the operator's operation intention by voice recognition processing of spoken commands of the operator; and the controller controls the driving device to displace the auxiliary operating member of the operating part into the nearby position based on the voice recognition processing.

27: A vehicle input device comprising:
an operating part arranged within a vehicle passenger compartment and including at least one movable operation switch of a plurality of operation switches;
a movable support mechanism for supporting the moveable operation switch of the operating part to move between a distant position farther away from an operator and a nearby position closer to the operator;
a driving device for generating a drive force to displace the movable operation switch of the operating part;
a controller for controlling the driving device; and
an operation intention detector for detecting an operator's intention to operate the movable operation switch of the operating part,
wherein the controller controls the driving device to displace the movable operation switch of the operating part into the nearby position if the operator's operation intention is detected by the operation intention detector,
wherein the plurality of operation switches include a joystick knob, operated with two left-right and front-rear axes, and the operation intention detector includes at least one photoelectric sensor provided between the movable operation switch and the joystick knob, for detecting an object approaching or making contact with the operation intention detector.

28: The vehicle input device according to claim 27, wherein the controller controls the driving device to displace the movable operation switch into the distant position if the operator's operation intention is not detected by the operation intention detector while the movable operating switch is in the nearby position.

29: The vehicle input device according to claim 27, wherein the operation part comprises a remote controller.

30: The vehicle input device according to claim 27, wherein the operation intention detector includes a capacitance sensor provided in at least one of the plurality of operation switches, and the controller controls the driving device to displace the movable operation switch into the nearby position based on an output signal of the capacitance sensor when the operator's hand approaches or makes contact with the corresponding operating switch provided with the capacitance sensor.

31: The vehicle input device according to claim 28, wherein the operating part comprises a remote controller.

32: The vehicle input device according to claim 28, wherein the operation intention detector includes a capacitance sensor provided in at least one of the plurality of operation switches, and the controller controls the driving device to display the movable operation switch into the nearby position based on an output signal of the capacitance sensor when the operator's hand approaches or makes contact with the corresponding operating switch provided with the capacitance sensor.

33: The vehicle input device according to claim 29, wherein the operation intention detector includes a capacitance sensor provided in at least one of the plurality of operation switches, and the controller controls the driving device to displace the movable operation switch into the nearby position based on an output signal of the capacitance sensor when the operator's hand approaches or makes contact with the corresponding operating switch provided with the capacitance sensor.

34: The vehicle input device according to claim 31, wherein the operation intention detector includes a capacitance sensor provided in at least one of the plurality of operation switches, and the controller controls the driving device to displace the movable operation switch into the nearby position based on an output signal of the capacitance sensor when the operator's hand approaches or makes contact with the corresponding operating switch provided with the capacitance sensor.
